(19) United States
(12) Patent Application Publication
(10) Pub. No.: US 2017/0317691 A1
(43) Pub. Date: Nov. 2, 2017

(54) HARDWARE-ASSISTED PROTECTION FOR SYNCHRONOUS INPUT/OUTPUT

(71) Applicant: INTERNATIONAL BUSINESS MACHINES CORPORATION, Armonk, NY (US)

(72) Inventors: David F. Craddock, New Paltz, NY (US); Matthias Klein, Wappingers Falls, NY (US); Eric N. Lais, Georgetown, TX (US); Peter G. Sutton, Lagrangeville, NY (US); Harry M. Yudenfriend, Poughkeepsie, NY (US)

(21) Appl. No.: 15/142,127

(22) Filed: Apr. 29, 2016

(51) Int. Cl. H03M 13/09; H03M 13/00

(52) U.S. Cl. CPC H03M 13/09; H03M 13/6566

(57) ABSTRACT

Examples of techniques for hardware assisted data protection are disclosed. In one example implementation according to aspects of the present disclosure, a method may include receiving a read data record comprising at least one memory write, the read data record having an associated cyclic redundancy check (CRC). The method may further include calculating, by a hardware module, an expected CRC for the read data record. Additionally, the method may include comparing the expected CRC to a known CRC stored in a known CRC data store. Finally, the method may include authenticating the read data record when the expected CRC matches a corresponding known CRC.

### BACKGROUND

The present disclosure relates generally to input/output (I/O) on a processing system and, more particularly, to hardware-assisted protection for synchronous I/O.

Storage Area Networks (SANs), as described by the Storage Networking Industry Association (SNIA), are high performance networks that enable storage devices and computer systems to communicate with each other. In large enterprises, multiple computer systems or servers have access to multiple storage control units within the SAN. Typical connections between the servers and control units use technologies such as Ethernet or Fibre-Channel, with the associated switches, I/O adapters, device drivers and multiple layers of a protocol stack. Fibre-channel, for example, as defined by the INCITS T11 Committee, defines physical and link layers FC0, FC1, FC2 and FC-4 transport layers such as the Fibre Channel Protocol (FCP) for SCSI and FC-SB-3 for Fibre Connectivity (FICON).

There are many examples of synchronous and asynchronous I/O access methods, each with their own advantages and disadvantages. Synchronous I/O causes a software thread to be blocked while waiting for the I/O to complete, but avoids context switches and interrupts. This works well when the I/O is locally attached with minimal access latency, but as access times increase, the non-productive processor overhead of waiting for the I/O to complete becomes unacceptable for large multi-processing servers.

The current state of the art for server access to SAN storage, with its associated protocol over-head, is to use asynchronous I/O access methods. The large variation in access times, and even the minimum access times, of SAN storage with today's protocols such as Fibre-Channel, make synchronous I/O access unacceptable. Moreover, in traditional storage protocols, a dedicated channel adapter may be utilized to perform a cyclic redundancy check (CRC) for protection of the data transferred.

### SUMMARY

According to examples of the present disclose, techniques including methods, systems, and/or computer program products for hardware assisted data protection are provided. An example method may include a method may include receiving a read data record comprising at least one memory write, the read data record having an associated cyclic redundancy check (CRC). The method may further include calculating, by a hardware module, an expected CRC for the read data record. Additionally, the method may include comparing the expected CRC to a known CRC stored in a known CRC data store. Finally, the method may include authenticating the read data record when the expected CRC matches a corresponding known CRC.

An alternate example method for hardware assisted data protection may include calculating, by a hardware module, a cyclic redundancy check (CRC) for a write data record to be written to a storage device, the write data record comprising at least one memory read response. The method may further include appending the CRC to the write data record. Finally, the method may include transmitting the write data record having the CRC appended thereto to the storage device.

An alternate example method for hardware assisted data protection may include calculating, by a hardware module, a cyclic redundancy check (CRC) for a write data record to be written to a storage device, the write data record comprising at least one memory read response. The method may further include appending the CRC to the write data record. The method may further include storing the CRC for the write data record in a known CRC data store. The method may further include transmitting the write data record having the CRC appended thereto to the storage device. The method may further include receiving a read data record comprising at least one memory write, the read data record having an associated CRC. The method may further include calculating, by the hardware module, an expected CRC for the read data record. The method may further include comparing the expected CRC to a known CRC stored in the known CRC data store. Finally, the method may include authenticating the read data record when the expected CRC matches a corresponding known CRC.

Additional features and advantages are realized through the techniques of the present disclosure. Other aspects are described in detail herein and are considered a part of the disclosure. For a better understanding of the present disclosure with the advantages and the features, refer to the following description and to the drawings.

### BRIEF DESCRIPTION OF THE DRAWINGS

The subject matter which is regarded as the invention is particularly pointed out and distinctly claimed in the claims at the conclusion of the specification. The foregoing and other features, and advantages thereof, are apparent from the following detailed description taken in conjunction with the accompanying drawings in which:

FIG. 1 illustrates a communication schematic comparing synchronous input/output (I/O) and traditional I/O according to aspects of the present disclosure;

FIG. 2 illustrates a block diagram of a system for performing synchronous I/O according to aspects of the present disclosure;

FIG. 3 illustrates a block diagram of an environment including a synchronous I/O link interface according to aspects of the present disclosure;

FIG. 4 illustrates a block diagram of an environment for performing synchronous I/O with respect to a mailbox command and read operation according to aspects of the present disclosure;

FIG. 5 illustrates a block diagram of an environment for performing synchronous I/O with respect to a write operation according to aspects of the present disclosure;

FIG. 6 illustrates a flow diagram of a method for providing hardware-assisted protection for synchronous 10 according to aspects of the present disclosure; and

FIG. 7 illustrates a block diagram of a processing system for implementing the techniques described herein according to aspects of the present disclosure;

### DETAILED DESCRIPTION

Various implementations are described below by referring to several examples of techniques for providing hardware-assisted protection for synchronous input/output (I/O). Storage data may be protected, such as using a cyclic redundancy check (CRC) code that spans a transaction payload. When transmitting data using a synchronous I/O protocol, a computing host checks the CRC associated with the transaction payload for read operations and/or generates a CRC for write operations and associates the calculated CRC with the transaction payload. This is accomplished using hardware-assistance in the computing host utilizing an existing device table infrastructure in the computing host. This alleviates the need for a dedicated I/O channel hardware and/or software based CRC calculation on the computing host side.

According to examples of the present disclosure, for each synchronous I/O read transaction payload, hardware in the computing host calculates a CRC for each data record of the transaction payload and compares it to the CRC received from the storage device, such as a persistent storage control unit, as an appendix of the transaction payload. A CRC mismatch is reported as an invalid transaction payload, while a CRC match indicates a valid transaction payload. For each synchronous I/O write transaction payload, hardware in the computing host calculates a CRC for each data record of the transaction payload and appends the calculated CRC to the transaction payload that is sent to the persistent storage control unit.

In some implementations, the present techniques reduce latency and the number of intermediate steps for performing CRC checking or generation. Moreover, the present techniques avoid firmware-based CRC checking and generation, which is computationally expensive. Data is protected end-to-end instead of being regenerated multiple times in the path. The present techniques provide lower latency in the hardware path compared to legacy implementations with channel adapters performing a store and forward and recalculation of CRC. The present techniques also provide lower latency and reduced CPU cost compared to a synchronous I/O implementation with firmware or software generating or checking the CRC. These and other advantages will be apparent from the description that follows.

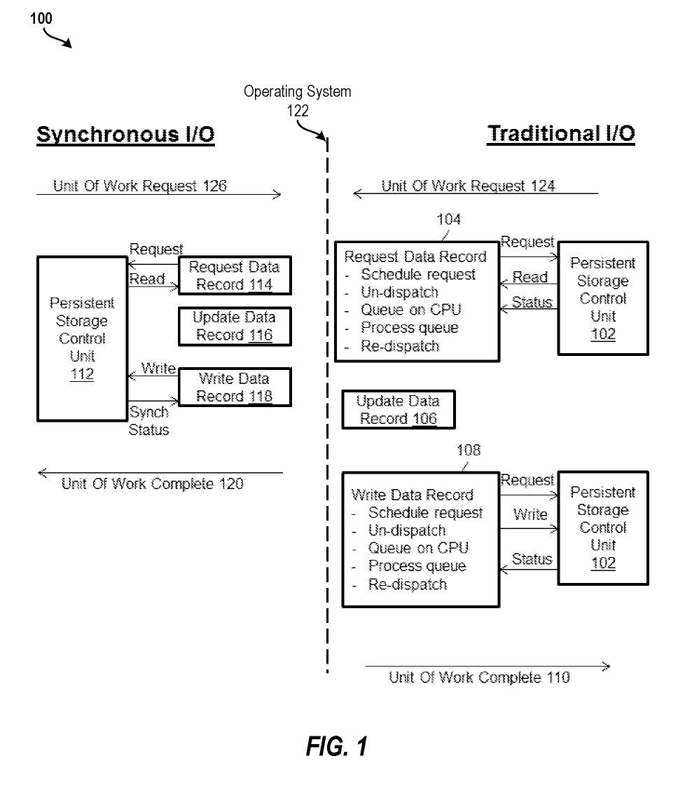

Turning now to FIG. 1, communication schematics 100 of a traditional I/O and a synchronous I/O when updating data stored on a peripheral storage device are generally shown according to aspects of the present disclosure. As shown on the right side of FIG. 1, performing traditional I/O operations includes receiving a unit of work request 124 at an operating system (OS) 122 in a logical partition (LPAR). The unit of work can be submitted, for example, from an application or middleware that is requesting an I/O operation. As used herein the term “unit of work” refers to dispatchable tasks or threads.

In response to receiving the unit of work request, the OS 122 performs the processing shown in block 104 to request a data record. This processing includes scheduling an I/O request by placing the I/O request on a queue for the persistent storage control unit (SCU) 102 that contains the requested data record 104, and then un-dispatching the unit of work. Alternatively, the application (or middleware) can receive control back after the I/O request is scheduled to possibly perform other processing, but eventually the application (or middleware) relinquishes control of the processor to allow other units of work to be dispatched and the application (or middleware) waits for the I/O to complete and to be notified when the data transfer has completed with or without errors.

When the persistent SCU 102 that contains the data record 104 is available for use and conditions permit, the I/O request is started by the OS issuing a start sub-channel instruction or other instruction appropriate for the I/O architecture. The channel subsystem validates the I/O request, places the request on a queue, selects a channel (link) to the persistent SCU 102, and when conditions permit begins execution. The I/O request is sent to a persistent SCU 102, and the persistent SCU 102 reads the requested data record from a storage device(s) of the persistent SCU 102. The read data record along with a completion status message is sent from the persistent SCU 102 to the OS 122. Once the completion status message (e.g., via an I/O interrupt message) is received by the OS 122, the OS 122 requests that the unit of work be re-dispatched by adding the unit of work to the dispatch queue. This includes re-dispatching the LPAR to process the interrupt and retrieving, by the I/O supervisor in the OS, the status and scheduling the application (or middleware) to resume processing. When the unit of work reaches the top of the dispatch queue, the unit of work is re-dispatched.

Still referring to the traditional I/O, once the data record is received by the OS 122, the OS 122 performs the processing in block 106 to update the data record that was received from the persistent SCU 102. At block 108, the updated data record is written to the persistent SCU 102. As shown in FIG. 1, this includes the OS 122 scheduling an I/O request and then un-dispatching the instruction. The I/O request is sent to a persistent SCU 102, and the persistent SCU 102 writes the data record to a storage device(s) of the persistent SCU 102. A completion status message (e.g., an interruption message) is sent from the persistent SCU 102 to the OS 122. Once the completion status message is received by the OS 122, the OS 122 requests that the unit of work be re-dispatched by adding the unit of work to the dispatch queue. When the unit of work reaches the top of the dispatch queue, the unit of work is re-dispatched. At this point, the unit of work is complete. As shown in FIG. 1, the OS 122 can perform other tasks, or multi-task, while waiting for the I/O request to be serviced by the persistent SCU 102.

The traditional I/O process is contrasted with a synchronous I/O process. As shown in FIG. 1, performing a synchronous I/O includes receiving a unit of work request at the OS 122. In response to receiving the unit of work request, the OS 122 performs the processing shown in block 114 which includes synchronously requesting a data record from the persistent SCU 112 and waiting until the requested data record is received from the persistent SCU 112. Once the data record is received by the OS 122, the OS 122 performs the processing in block 116 to update the data record. At block 118, the updated data record is synchronously written to the persistent SCU 112. A synchronous status message is sent from the persistent SCU 112 to the OS 122 to indicate the data has been successfully written. At this point, the unit of work is complete. As shown in FIG. 1, the OS 122 is waiting for the I/O request to be serviced by the persistent SCU 112 and is not performing other tasks, or multi-tasking, while waiting for the I/O request to be serviced. Thus, in an embodiment, the unit of work remains active (i.e., it is not un-dispatched and re-dispatched) until the OS is notified that the I/O request is completed (e.g., data has been read from persistent SCU, data has been written to persistent SCU, error condition has been detected, etc.).

Thus, as shown in FIG. 1, synchronous I/O provides an interface between a server and a persistent SCU that has sufficiently low overhead to allow an OS to synchronously read or write one or more data records. In addition to the low overhead protocol of the link, an OS executing on the server can avoid the scheduling and interruption overhead by using a synchronous command to read or write one or more data records. Thus, embodiments of synchronous I/O as described herein when compared to traditional I/O not only reduce the wait time for receiving data from a persistent SCU, they also eliminate steps taken by a server to service the I/O request. Steps that are eliminated can include the un-dispatching and re-dispatching of a unit of work both when a request to read data is sent to the persistent SCU and when a request to write data is sent to the persistent SCU. This also provides benefits in avoiding pollution of the processor cache that would be caused by un-dispatching and re-dispatching of work.

As used herein, the term “persistent storage control unit” or “persistent SCU” refers to a storage area network (SAN) attached storage subsystem with a media that stores data that can be accessed after a power failure. As known in the art, persistent SCUs are utilized to provide secure data storage even in the event of a system failure. Persistent SCUs can also provide backup and replication to avoid data loss. A single persistent SCU is typically attached to a SAN and accessible by multiple processors.

As used herein, the term “synchronous I/O” refers to a CPU synchronous command that is used to read or write one or more data records, such that when the command completes successfully, the one or more data records are guaranteed to have been transferred to or from the persistent storage control unit into host processor memory.

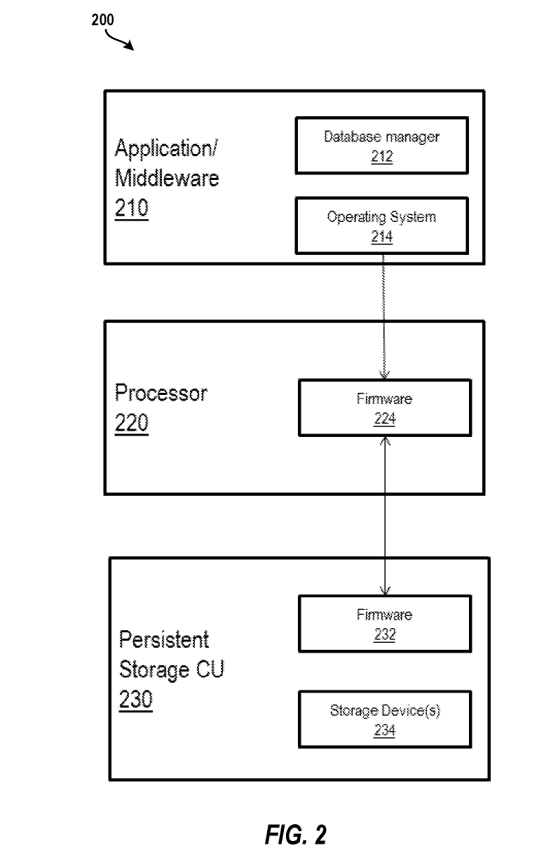

Turning now to FIG. 2, a block diagram of a system 200 (e.g., synchronous system) for performing synchronous I/O is generally shown according to aspects of the present disclosure. The system 200 shown in FIG. 2 includes one or more application/middleware 210, one or more physical processors 220, and one or more persistent SCUs 230. The application/middleware 210 can include any application software that utilizes access to data located on the persistent SCU 230 such as, but not limited to a relational database manager 212 (e.g. DB2), an OS 214, a filesystem (e.g., z/OS Distributed File Service System z File System produced by IBM), a hierarchical database manager (e.g., IMS® produced by IBM), or an access method used by applications (e.g., virtual storage access method, queued sequential access method, basic sequential access method). As shown in FIG. 2, the database manager 212 can communicate with an OS 214 to communicate a unit of work request that utilizes access to the persistent SCU 230. The OS 214 receives the unit of work request and communicates with firmware 224 located on the processor 220 to request a data record from the persistent SCU 230, to receive the data record from the persistent SCU 230, to update the received data record, to request the persistent SCU 230 to write the updated data record, and to receive a confirmation that the updated data recorded was successfully written to the persistent SCU 230. The firmware 224 accepts the synchronous requests from the OS 214 and processes them. Firmware 232 located on the persistent SCU 230 communicates with the firmware 224 located on the processor 220 to service the requests from the processor 220 in a synchronous manner.

As used herein, the term “firmware” refers to privileged code running on the processor that interfaces with the hardware used for the I/O communications; a hypervisor; and/or other OS software.

Embodiments described herein utilize peripheral component interconnect express (PCIe) as an example of a low latency I/O interface that may be implemented by embodiments. Other low latency I/O interfaces, such as, but not limited to Infiniband™ as defined by the InfiniBand Trade Association and zSystems coupling links can also be implemented by embodiments.

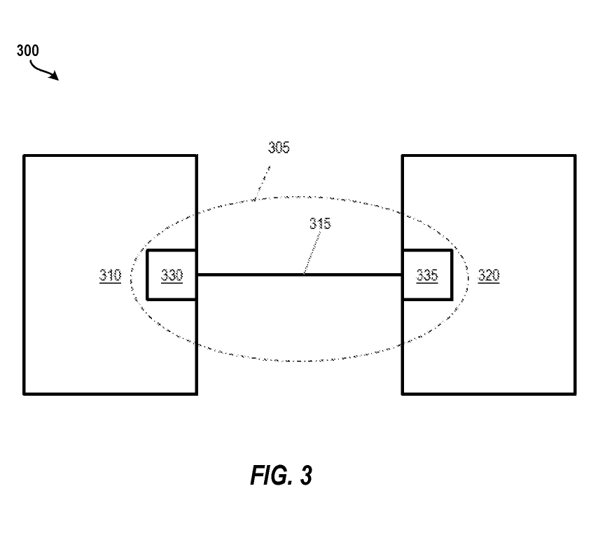

Turning now to FIG. 3, a block diagram of an environment 300 including a synchronous I/O link interface 305 is depicted according to aspects of the present disclosure. As shown in FIG. 3, the environment 300 utilizes the synchronous I/O link interface 305 as an interface between a server (e.g., a system 310) and a persistent SCU (e.g., a persistent SCU 320). The synchronous I/O link interface 305 has sufficiently low latency and protocol overhead to allow an OS of the system 310 to synchronously read or write one or more data records from the persistent SCU 320. In addition to the low protocol overhead of the link, the OS can avoid the overhead associated with scheduling and interrupts by using a synchronous command via the synchronous I/O link interface 305 to read or write one or more data records. The synchronous I/O link interface 305, for example, can be provided as an optical interface based on any PCIe base specification (as defined by the PCI-SIG) using the transaction, data link, and physical layers. The synchronous I/O link interface 305 may further include replay buffers and acknowledgment credits to sustain full bandwidth.

The system 310 is configured to provide at least one synchronous I/O link interface 305 having at least one synchronous I/O link 315 to allow connection to at least one persistent SCU (e.g., persistent SCU 320). It can be appreciated that two or more synchronous I/O links 315 may be utilized for each connection to a persistent SCU. It can also be appreciated that two or more synchronous I/O links 315 may support switch connections to a persistent SCU. In an exemplary embodiment, where PCIe is utilized, the system 310 comprises a PCIe root complex 330 for the interface link 315, while the persistent SCU 320 comprises a PCIe endpoint 335 for the control unit synchronous I/O interface 305.

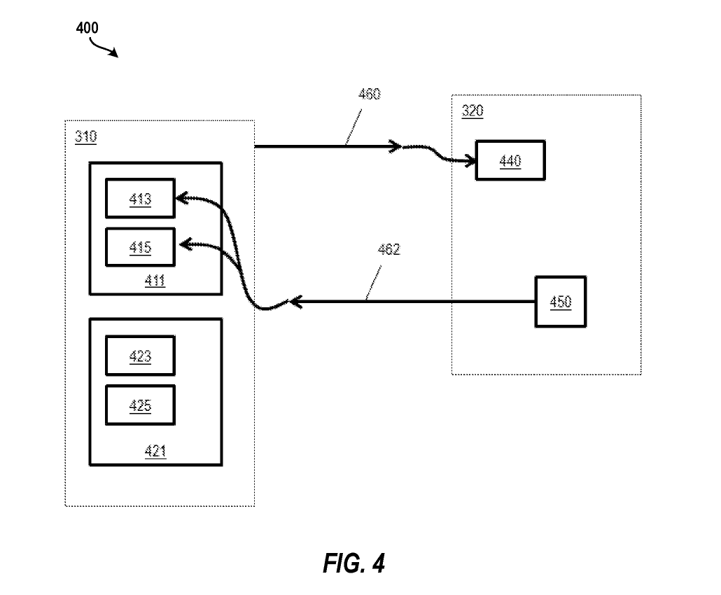

Turning now to FIG. 4, a block diagram of an environment 400 for performing synchronous I/O with respect to a mailbox command and read operation is depicted according to aspects of the present disclosure. As shown in FIG. 4, the environment 400 includes a system 310 (e.g., includes the application/middleware 210 and processor 220 of FIG. 2) and a persistent SCU 320 (e.g., includes persistent CU 230 of FIG. 2). The system 310 includes a LPAR 411 comprising memory locations for a data record 413 and an associated suffix 415 and a status area 421 comprising a device table entry (DTE) 423 and a status field 425. DTE 423 is an example of a data structure used by the firmware to store the mappings, such as, between virtual addresses and physical addresses. Similarly, a function table entry (FTE) is an example of a data structure used by a function table to indicate access to a specified synchronous I/O link. The persistent SCU 320 includes at least one mailbox 440 and a data record 450.

In operation, synchronous I/O commands issued by the OS of the system 310 are processed by the firmware 224 to build a mailbox command 460 that is forwarded to the persistent SCU 320. For example, upon processing a synchronization I/O command for the OS by a firmware of the system 310, the firmware prepares hardware of the system 310 and sends the mailbox command 460 to the persistent SCU 320. The mailbox command 460 is sent to the persistent SCU 320 in one or more memory write operations (e.g., over PCIe, using a PCIe base mailbox address that has been determined during an initialization sequence described below). A plurality of mailboxes can be supported by the persistent SCU 320 for each synchronous I/O link 305. A first mailbox location of the plurality of mailboxes can start at the base mailbox address, with each subsequent mailbox location sequentially located 256-bytes after each other. After the mailbox command 460 is sent, the firmware can poll the status area 421 (e.g., a status field 425) for completion or error responses. In embodiments, the status area 421 is located in privileged memory of the system 310 and is not accessible by the OS executing on the system 310. The status area 421 is accessible by the firmware on the system 310 and the firmware can communicate selected contents (or information related to or based on contents) of the status area 421 to the OS (e.g., via a command response block).

In general, a single mailbox command 460 is issued to each mailbox at a time. A subsequent mailbox command will not issue to a mailbox 440 until a previous mailbox command has completed or an error condition (such as a timeout, when the data is not in cache, error in the command request parameters, etc.) has been detected. Successive mailbox commands for a given mailbox 440 can be identified by a monotonically increasing sequence number. Mailboxes can be selected in any random order. The persistent SCU 320 polls all mailboxes for each synchronous I/O link 305 and can process the commands in one or more mailboxes in any order. In an embodiment, the persistent SCU 320 polls four mailboxes for each synchronous I/O link 305. Receipt of a new mailbox command with an incremented sequence number provides confirmation that the previous command has been completed (either successfully or in error by the system 310). In an embodiment, the sequence number is also used to determine an offset of the status area 421. The mailbox command can be of a format that includes 128-bytes. The mailbox command can be extended by an additional 64-bytes or more in order to transfer additional data records. In an embodiment, a bit in the mailbox command is set to indicate the absence or presence of the additional data records.

The mailbox command can further specify the type of data transfer operations, e.g., via an operation code. Data transfer operations include read data and write data operations. A read operation transfers one or more data records from the persistent SCU 320 to a memory of the system 310. A write operation transfers one or more data records from the memory of the system 310 to the storage persistent SCU 320. In embodiments, data transfer operations can also include requesting that the persistent SCU 320 return its Worldwide Node Name (WWNN) to the firmware in the server. In further embodiments, data transfer operations can also request that diagnostic information be gathered and stored in the persistent SCU 320.

In any of the data transfer operations the contents of the mailbox command can be protected by a checksum. In an embodiment, if the persistent SCU 320 detects a checksum error, a response code to indicate the checksum error is returned. Continuing with FIG. 4, a synchronous I/O read data record operation will now be described. For instance, if a mailbox command 460 includes an operation code set to read, the persistent SCU 320 determines if the data record or records 450 are readily available, such that the data transfer can be initiated in a sufficiently small time to allow the read to complete synchronously. If the data record or records 450 are not readily available (or if any errors are detected with this mailbox command 460), a completion status is transferred back to the system 310. If the read data records are readily available, the persistent SCU 320 provides the data record 450.

In an embodiment, the persistent SCU 320 processes the mailbox command 460, fetches the data record 450, provides CRC protection, and transfers/provides the data record 450 over the synchronous I/O link 305. The persistent SCU 320 can provide the data record 450 as sequential memory writes over PCIe, using the PCIe addresses provided in the mailbox command 460. Each data record may utilize either one or two PCIe addresses for the transfer as specified in the mailbox command 460. For example, if length fields in the mailbox command indicate the data record is to be transferred in a single contiguous PCIe address range, only one starting PCIe address is utilized for each record, with each successive PCIe memory write using contiguous PCIe addresses. In embodiments, the length fields specify the length in bytes of each data record to be transferred.

The data record 450 can include a data portion and a suffix stored respectively on data record 413 and suffix 415 memory locations of the logical partition 411 after the data record 450 is provided. The data record 413 can be count key data (CKD) or extended count key data (ECKD). The data record 413 can also be utilized under small computer system interface (SCSI) standards, such as SCSI fixed block commands. Regarding the suffix, at the end of each data record 450, an additional 4-bytes can be transferred comprising a 32-bit CRC that has been accumulated for all the data in the data record 450. The metadata of the suffix 415 can be created by an operating system file system used for managing a data efficiently. This can be transferred in the last memory write transaction layer packet along with the last bytes of the data record 450, or in an additional memory write.

In addition, a host bridge of the system 310 performs address translation and protection checks (e.g., on the PCIe address used for the transfers) and provides an indication in the DTE 423 to the firmware of the system 310 when the data read 462 is complete. The host bridge can also validate that the received CRC matches the value accumulated on the data transferred. After the last data record and corresponding CRC have been initiated on the synchronous I/O link 305, the persistent SCU 320 considers this mailbox command 460 complete and must be ready to accept a new command in this mailbox 440.

In an exemplary embodiment, the system 310 considers the mailbox command 460 complete when all the data records 450 have been completely received and the corresponding CRC has been successfully validated. For example, the firmware performs a check of the status area 421 to determine if the data read 462 was performed without error (e.g., determines if the DTE 423 indicates ‘done’ or ‘error’). If the data read 462 was performed without error and is complete, the firmware then completes the synchronous I/O command. The system 310 will also consider the mailbox command 460 complete if an error is detected during the data read 462 or CRC checking process, error status is received from the persistent SCU 320, or the data read 462 does not complete within the timeout period for the read operation.

Embodiments of the mailbox command can also include a channel image identifier that corresponds to a logical path previously initialized by the establish-logical-path procedure, for example over a fibre-channel interface. If the logical path has not been previously established, a response code corresponding to this condition can be written to the status area 421 to indicate that the logical path was not previously established.

The mailbox command block can also include a persistent SCU image identifier that corresponds to a logical path previously initialized by the establish-logical-path procedure. If the logical path has not been previously established, a response code corresponding to this condition can be written to the status area 421 to indicate that the logical path was not previously established.

The mailbox command block can also include a device address within the logical control unit (e.g., a specific portion of the direct access storage device located in the storage control unit) that indicates the address of the device to which the mailbox command is directed. The device address should be configured to the persistent SCU specified, otherwise the persistent SCU 320 can return a response code (e.g., to the status area 421 in the system 310) to indicate this condition.

The mailbox command block can also include a link token that is negotiated by the channel and the persistent SCU 320 each time the synchronous I/O link is initialized. If the persistent SCU 320 does not recognize the link token, it can return a value to the status area 421 that indicates this condition.

The mailbox command block can also include a WWNN that indicates the WWNN of the persistent SCU to which the command is addressed. In embodiments, it is defined to be the 64-bit IEEE registered name identifier as specified in the T11 Fibre-Channel Framing and Signaling 4 (FC-FS-4) document. If the specified WWNN does not match that of the receiving persistent SCU, then a response code indicating this condition is returned to processor.

The mailbox command block can also include device specific information that is used to specify parameters specific to this command. For example, for enterprise disk attachment when a write or read is specified by the operation code, device specific information can include the prefix channel command. In another example, when the operation code specifies that the command is a diagnostic command, the device specific information can include a timestamp representing the time at which this command was initiated and a reason code.

The mailbox command can also include a record count that specifies the number of records to be transferred by this synchronous I/O command (or mailbox command).

When PCIe is being utilized with a mailbox command that includes multiple 32 bit words, the mailbox command can include one or more PCIe data addresses in the following format: PCIe data address bits 63:32 in word “n” to specify the word-aligned address of the location in memory (e.g., in the processor) where data will be fetched for a write and stored for a read operation; and PCIe data addressing bits 31:2 in word “n+1.” In addition word n+1 can include an end or record bit that can be set to indicate that the last word specified is the last word of the record that is to be read or written.

The mailbox command can also include a mailbox valid bit(s) that indicates whether the mailbox command is valid and whether the entire mailbox command has been received.

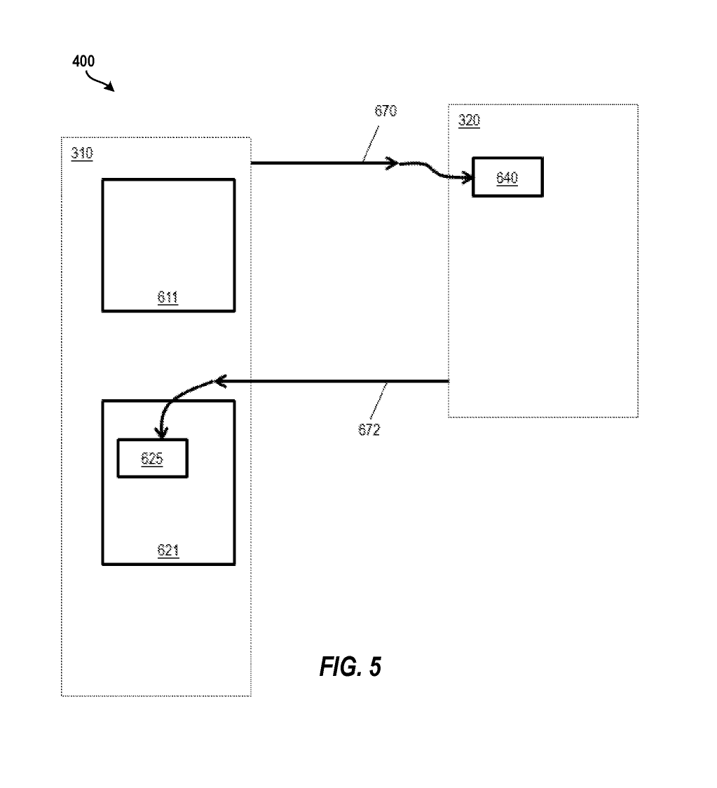

In view of the above, a synchronous I/O write data record operation will now be described with respect to FIG. 5 in accordance with an embodiment. As shown in FIG. 5, the environment 500 includes a system 310 and a persistent SCU 320. The system 310 includes a logical partition 511 comprising memory locations for a data record 513 and a suffix 515 and a status area 521 comprising a DTE 523 and a status field 525. The persistent SCU 320 includes at least one mailbox 540 and a data record 550 once written.

In operation, for example, upon processing a synchronization I/O command for the OS by a firmware of the system 310, the firmware prepares hardware of the system 310 and sends the mailbox command 560 to mailbox 540 of the persistent SCU 320. As noted above, a plurality of mailboxes can be supported by the persistent SCU 320 for each synchronous I/O link 305. Further, after the mailbox command 560 is sent, the firmware can poll the status area 521 (e.g., a status field 525) for completion or error responses.

If a mailbox command 560, issued to mailbox 540, includes an operation code set to write, the persistent SCU 320 determines if it is able to accept the transfer of the data record or records 550. If the persistent SCU 320 is not able to accept the transfer (or if any errors are detected with this mailbox command 560), a completion status is transferred back to the system 310. If the persistent SCU 320 is able to accept the transfer, the persistent SCU 320 issues memory read requests 565 for the data.

In an embodiment, the persistent SCU 320 processes the mailbox command 560 and issues a read request 565 over PCIe (using the PCIe addresses provided in the mailbox command 560) to fetch the data including the data record 513 and the suffix 515. In response to the read request 565, the host bridge of the system 310 performs address translation and protection checks on the PCIe addresses used for the transfers.

Further, the system 310 responds with memory read responses 570 to these requests. That is, read responses 570 are provided by the system 310 over the synchronous I/O link 305 to the persistent SCU 320 such that the data record 550 can be written. Each data record may utilize either one or two PCIe addresses for the transfer as specified in the mailbox command 560. For example, if the length fields in the mailbox command indicate the entire record can be transferred using a single contiguous PCIe address range, only one starting PCIe address is utilized for each record, with each successive PCIe memory read request using contiguous PCIe addresses. At the end of each data record, the additional 8-bytes will be transferred consisting of the 32-bit CRC that has been accumulated for all the data in the record and optionally an LRC or other protection data that has also been accumulated. The total number of bytes requested for each record can be 8-bytes greater than the length of the record to include the CRC protection bytes and the additional 4-bytes for a longitudinal redundancy check (LRC).

After the data and CRC/LRC protection bytes have been successfully received, the persistent SCU 320 responds by issuing a memory write 572 (e.g., of 8-bytes of data). The persistent SCU 320 considers this mailbox command 560 complete after initiating this status transfer and must be ready to accept a new command in this mailbox 540. The system 310 will consider the mailbox command 560 complete when the status transfer has been received. For example, the firmware performs a check of the status area 521 (e.g., determines if the DTE 523 indicates ‘done’ or ‘error’). The system 310 will also consider the mailbox command 560 complete if an error is detected during the data transfer, error status is received from the persistent SCU 320, or the status is not received within the timeout period for this operation.

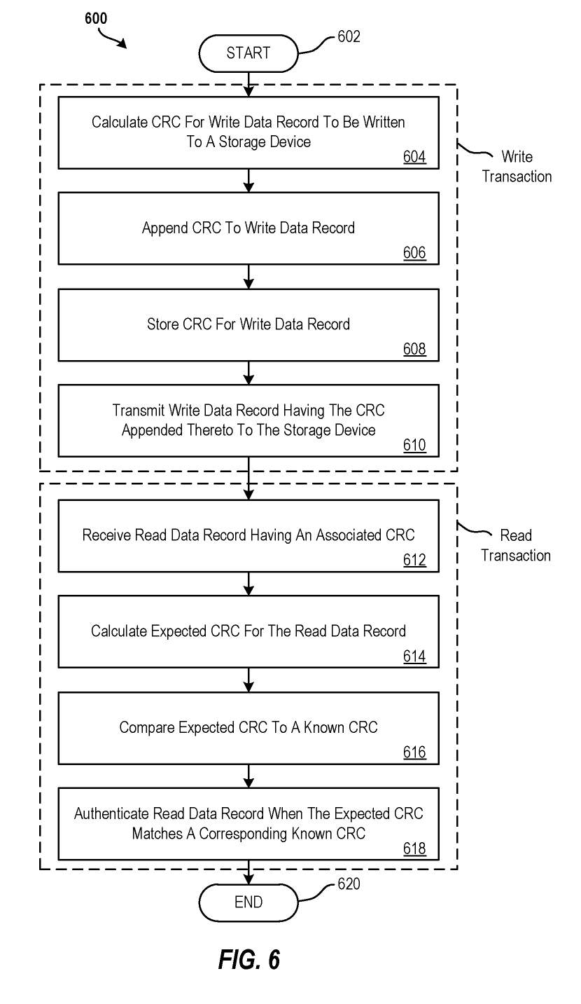

Turning now to FIG. 6, a method 600 for providing hardware-assisted protection for synchronous input/output is illustrated. A discussed above, storage data is protected by a CRC code that spans the data record 450. When transmitting data using the synchronous I/O protocol discussed herein, the CRC associated with the data record is checked (for read operations) or generated (for write operations). Instead of relying on a dedicated channel adapter to perform the storage CRC checking, the CRC is performed within a root complex (e.g., PCIe root complex 330 of FIG. 3) of a host system (e.g., system 310 of FIG. 3). For each transaction (e.g., for 4k data), the corresponding CRC is calculated while the data is being transferred through the root complex.

To accomplish this, a bus mode is created that enables devices to be identified as requiring CRC computation on a bus number basis (e.g., as an extension to the existing native, tunneled, and firmware-managed modes). Each synchronous I/O endpoint device (e.g., persistent SCU 320) can have, for example, up to 256 or 512 functions associated with its bus number. In examples, the various functions are differentiated by the use of PCI address bits (e.g. bits 47:40). Functions can be reserved for high level protocol functions or assigned to a synchronous I/O CRC transaction, identified by the use of flag bits in the DTE.

When a PCIe memory read or write request is received by the host bridge, the device table entry associated with this transaction is located using the bus number and PCI address bits described above. The flags in the DTE identify this request as a CRC transaction within the synchronous I/O protocol, the host bridge hardware of the host system (e.g., system 310 of FIG. 3) initializes a CRC context for the transaction, containing the current CRC and the byte count for the data record. The initial value for the CRC context is provided by firmware in the device table in memory. For each PCIe packet of that transaction payload (i.e., originating from a particular bus and range of PCIe addresses), the CRC of the data record is calculated and updated in the CRC context within the DTE by the host bridge of the host system.

When the final PCIe packet associated with a transaction payload arrives (identified by the data for this DTE reaching the byte count specified in the DTE), the host bridge of the host system recognizes the end of the transaction. For synchronous I/O read transactions, the host bridge compares the received CRC from the storage control unit, which is received as the final section of the transaction payload data, with the CRC calculated by the host system. The result is written back into the CRC context within the DTE along with a “done” indication, signaling completion of the transaction to firmware. For synchronous I/O write transactions, the storage control unit requests the calculated CRC (and/or LRC) in addition to the data record within the transaction payload. This calculated protection portion is sent to the storage control unit by the host bridge appending the CRC/LRC to the data record fetched from server memory.

Returning to FIG. 6, the method 600 begins at block 602 and continues to block 604. A write transaction is described referring to blocks 604, 606, 608, and 610. At block 604, the method 600 includes calculating, by a hardware module, a cyclic redundancy check (CRC) for a write data record to be written to a storage device, the write data record comprising at least one memory read response (e.g., PCIe packets). At block 606, the method 600 includes appending the CRC to the write data record. At block 608, the method 600 includes storing the CRC for the write data record in a known CRC data store. At block 610, the method 600 includes transmitting the write data record having the CRC appended thereto to the storage device.

A read transaction is now described referring to blocks 612, 614, 616, and 618. At block 612, the method 600 includes receiving a read data record comprising at least one memory write (e.g., PCIe memory write), the read data record having an associated CRC. At block 614, the method 600 includes calculating, by the hardware module, an expected CRC for the read data record. At block 616, the method 600 includes comparing, comparing the expected CRC to a known CRC stored in the known CRC data store. At block 618, the method 600 includes authenticating the read data record when the expected CRC matches a corresponding known CRC. The method 600 continues to block 620 and terminates.

Additional processes also may be included. For example, the method 600 may further include rejecting the read data record when the expected CRC does not match the corresponding known CRC. In examples, the hardware module is comprised in an input/output (I/O) hub of a communications interface, such as of system 310 of FIG. 3. The CRC for the write data record may be stored in in a corresponding device table entry of the I/O hub of the communications interface. In examples, multiple data records may be transferred, with each being associated with a device table entry and its CRC context. In some examples, each of the plurality of device table entries, may be associated on a peripheral component interconnect express (PCIe) bus number level.

It should be understood that the processes depicted in FIG. 6 represent illustrations, and that other processes may be added or existing processes may be removed, modified, or rearranged without departing from the scope and spirit of the present disclosure. It should be appreciated that the read transaction process described in blocks 612, 614, 616, and 618 may be implemented separately from the write transaction process described in blocks 604, 606, 608, and 610, and vice versa. For example, the write transaction process may be used to write data synchronously with the CRC appended, but the read transaction could be executed via an alternate path such as FICON. In another example, the read transaction process could be executed synchronously and checked using the received CRC after data is written via an alternate path such as FICON.

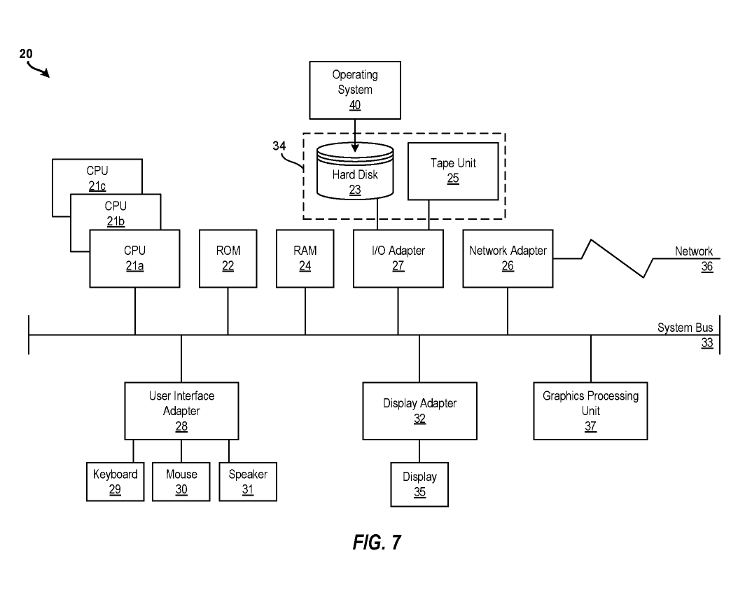

It is understood in advance that the present disclosure is capable of being implemented in conjunction with any other type of computing environment now known or later developed. For example, FIG. 7 illustrates a block diagram of a processing system 20 for implementing the techniques described herein. In examples, processing system 20 has one or more central processing units (processors) 21a, 21b, 21c, etc. (collectively or generically referred to as processor(s) 21 and/or as processing device(s)). In aspects of the present disclosure, each processor 21 may include a reduced instruction set computer (RISC) microprocessor. Processors 21 are coupled to system memory (e.g., random access memory (RAM) 24) and various other components via a system bus 33. Read only memory (ROM) 22 is coupled to system bus 33 and may include a basic input/output system (BIOS), which controls certain basic functions of processing system 20.

Further illustrated are an input/output (I/O) adapter 27 and a communications adapter 26 coupled to system bus 33. I/O adapter 27 may be a small computer system interface (SCSI) adapter that communicates with a hard disk 23 and/or a tape storage drive 25 or any other similar component. I/O adapter 27, hard disk 23, and tape storage device 25 are collectively referred to herein as mass storage 34. Operating system 40 for execution on processing system 20 may be stored in mass storage 34. A network adapter 26 interconnects system bus 33 with an outside network 36 enabling processing system 20 to communicate with other such systems.

A display (e.g., a display monitor) 35 is connected to system bus 33 by display adaptor 32, which may include a graphics adapter to improve the performance of graphics intensive applications and a video controller. In one aspect of the present disclosure, adapters 26, 27, and/or 32 may be connected to one or more I/O busses that are connected to system bus 33 via an intermediate bus bridge (not shown). Suitable I/O buses for connecting peripheral devices such as hard disk controllers, network adapters, and graphics adapters typically include common protocols, such as the Peripheral Component Interconnect (PCI). Additional input/output devices are shown as connected to system bus 33 via user interface adapter 28 and display adapter 32. A keyboard 29, mouse 30, and speaker 31 may be interconnected to system bus 33 via user interface adapter 28, which may include, for example, a Super I/O chip integrating multiple device adapters into a single integrated circuit.

In some aspects of the present disclosure, processing system 20 includes a graphics processing unit 37. Graphics processing unit 37 is a specialized electronic circuit designed to manipulate and alter memory to accelerate the creation of images in a frame buffer intended for output to a display. In general, graphics processing unit 37 is very efficient at manipulating computer graphics and image processing, and has a highly parallel structure that makes it more effective than general-purpose CPUs for algorithms where processing of large blocks of data is done in parallel.

Thus, as configured herein, processing system 20 includes processing capability in the form of processors 21, storage capability including system memory (e.g., RAM 24), and mass storage 34, input means such as keyboard 29 and mouse 30, and output capability including speaker 31 and display 35. In some aspects of the present disclosure, a portion of system memory (e.g., RAM 24) and mass storage 34 collectively store an operating system such as the AIX® operating system from IBM Corporation to coordinate the functions of the various components shown in processing system 20.

The present techniques may be implemented as a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some examples, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to aspects of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate the architecture, functionality, and operation of possible implementations of systems, methods, and computer program products according to various aspects of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various examples of the present disclosure have been presented for purposes of illustration, but are not intended to be exhaustive or limited to the embodiments disclosed. Many modifications and variations will be apparent to those of ordinary skill in the art without departing from the scope and spirit of the described techniques. The terminology used herein was chosen to best explain the principles of the present techniques, the practical application or technical improvement over technologies found in the marketplace, or to enable others of ordinary skill in the art to understand the techniques disclosed herein.

What is claimed is:

1. A computer-implemented method for hardware assisted data protection, the method comprising:
receiving a read data record comprising at least one memory write, the read data record having an associated cyclic redundancy check (CRC);
calculating, by a hardware module, an expected CRC for the read data record;
comparing the expected CRC to a known CRC stored in a known CRC data store; and
authenticating the read data record when the expected CRC matches a corresponding known CRC.

2. The computer-implemented method of claim 1, further comprising:
rejecting the read data record when the expected CRC does not match the corresponding known CRC.

3. The computer-implemented method of claim 1, wherein the hardware module is comprised in an input/output (I/O) hub of a communications interface.

4. The computer-implemented method of claim 3, wherein the known CRC for the read data record is stored in a corresponding device table entry of the I/O hub of the communications interface.

5. The computer-implemented method of claim 1, wherein the at least one memory write is associated with a device table entry.

6. The computer-implemented method of claim 1, wherein the at least one memory write is identified by a table entry on a peripheral component interconnect express (PCIe) bus number level.

7. The computer-implemented method of claim 1, wherein the read data record is received from a persistent storage control unit.

8. A computer-implemented method for hardware assisted data protection, the method comprising:
calculating, by a hardware module, a cyclic redundancy check (CRC) for a write data record to be written to a storage device, the write data record comprising at least one memory read response;
appending the CRC to the write data record; and
transmitting the write data record having the CRC appended thereto to the storage device.

9. The computer-implemented method of claim 8, further comprising:
storing the CRC for the write data record in a known CRC data store.

10. The computer-implemented method of claim 8, wherein the hardware module is comprised in an input/output (I/O) hub of a communications interface.

11. The computer-implemented method of claim 10, wherein the CRC for the write data record is stored in a corresponding device table entry of the I/O hub of the communications interface.

12. The computer-implemented method of claim 8, wherein the at least one memory read response is associated with a device table entry.

13. The computer-implemented method of claim 8, wherein the at least one memory read response is identified by a table entry on a peripheral component interconnect express (PCIe) bus number level.

14. The computer-implemented method of claim 8, wherein the storage device is a persistent storage control unit.

15. A computer-implemented method for hardware assisted data protection, the method comprising:
calculating, by a hardware module, a cyclic redundancy check (CRC) for a write data record to be written to a storage device, the write data record comprising at least one memory read response;
appending the CRC to the write data record;
storing the CRC for the write data record in a known CRC data store;
transmitting the write data record having the CRC appended thereto to the storage device;
receiving a read data record comprising at least one memory write, the read data record having an associated CRC;
calculating, by the hardware module, an expected CRC for the read data record;
comparing the expected CRC to a known CRC stored in the known CRC data store; and
authenticating the read data record when the expected CRC matches a corresponding known CRC.

16. The computer-implemented method of claim 15, further comprising:
rejecting the read data record when the expected CRC does not match the corresponding known CRC.

17. The computer-implemented method of claim 15, wherein the hardware module is comprised in an input/output (I/O) hub of a communications interface.

18. The computer-implemented method of claim 17, wherein the CRC for the write data record is stored in a corresponding device table entry of the I/O hub of the communications interface.

19. The computer-implemented method of claim 15, wherein the at least one memory read response is associated with a device table entry.

20. The computer-implemented method of claim 15, wherein the at least one memory read response is identified by a table entry on a peripheral component interconnect express (PCIe) bus number level.
